(19) United States
(12) Patent Application Publication
(10) Pub. No.: US 2024/0355849 A1
(43) Pub. Date: Oct. 24, 2024

(54) SEMICONDUCTOR PACKAGE, SEMICONDUCTOR DEVICE, AND METHOD FOR MANUFACTURING SEMICONDUCTOR PACKAGE

(71) Applicant: SONY SEMICONDUCTOR SOLUTIONS CORPORATION, KANAGAWA (JP)

(72) Inventors: TAICHI NATORI, KANAGAWA (JP); YUSUKE MORIYA, KANAGAWA (JP); KENSAKU MAEDA, KANAGAWA (JP)

(21) Appl. No.: 18/685,256

(22) PCT Filed: Jan. 31, 2022
(86) PCT No.: PCT/JP2022/003530

§ 371 Date: Feb. 21, 2024

(30) Foreign Application Priority Data
Sep. 7, 2021 (JP) 2021-145161

(51) Int. Cl. H01L 27/146

(52) U.S. Cl. CPC H01L 27/14621; H01L 27/14618; H01L 27/14627; H01L 27/14685

(57) ABSTRACT

To improve an optical property in a semiconductor package provided with an optical filter. The semiconductor package includes a multilayer film, an absorbing film, and a sensor substrate. In the semiconductor package, the multilayer film cuts off predetermined infrared light components of incident light. Moreover, in the semiconductor package, the absorbing film absorbs components of a predetermined absorption range from transmitted light having passed through the multilayer film. Furthermore, in the semiconductor package, the sensor substrate generates image data by photoelectrically converting light having passed through the absorbing film.

### TECHNICAL FIELD

The present technique relates to a semiconductor package. Specifically, the present technique relates to a semiconductor package provided with a solid-state image sensor, a semiconductor device, and a method for manufacturing the semiconductor package.

### BACKGROUND ART

Conventionally, in a semiconductor package provided with a solid-state image sensor, a cutoff filter for cutting off invisible light components such as infrared light is used to allow the solid-state image sensor to receive only visible light components. For example, a semiconductor package having a cavityless CSP (Chip Scale Package) is proposed, in which a multilayer film for cutting far-red light components of incident light is disposed as a cutoff filter (for example, see PTL 1). Moreover, the multilayer film of the semiconductor package reflects high-order diffraction components of light reflected from an image surface.

### CITATION LIST

### Patent Literature

[PTL 1]
JP 2012-175461A

### SUMMARY

### Technical Problem

In the conventional art, high-order diffraction components of light reflected from the image surface are reflected by the multilayer film, thereby suppressing flare. However, in the conventional art, the cutoff wavelength of the multilayer film shifts to the short wavelength side as the incident angle of incident light increases. The wavelength shift prevents infrared light components with large incident angles from being sufficiently cut off, so that the optical property of the multilayer film may deteriorate.

The present technique has been devised in view of such circumstances. An object of the present technique is to improve an optical property in a semiconductor package provided with an optical filter.

### Solution to Problem

The present technique has been devised to solve the problem. A first aspect of the present technique is a semiconductor package including: a multilayer film that cuts off predetermined infrared light components of incident light; an absorbing film that absorbs components of a predetermined absorption range from transmitted light having passed through the multilayer film; and a sensor substrate that generates image data by photoelectrically converting light having passed through the absorbing film, and a method for manufacturing the semiconductor package. This provides the effect of improving an optical property.

The first aspect may further include a glass and a seal resin applied between the glass and the sensor substrate. This provides the effect of sealing the sensor substrate.

In the first aspect, the multilayer film may be formed on one of both sides of the glass, the absorbing film may be formed between the other of both surfaces of the glass and the seal resin, and the seal resin may be applied without forming a cavity. This provides the effect of suppressing image quality degradation caused by dust in the multilayer film.

In the first aspect, the multilayer film may cover one of both sides of the glass and the sides of the glass, and the absorbing film may be formed between the other of both surfaces of the glass and the seal resin. This provides the effect of sealing the sensor substrate.

In the first aspect, the multilayer film may include a first multilayer film and a second multilayer film, the first multilayer film may be formed on one of both sides of the glass, and the second multilayer film may be formed between the other of both surfaces of the glass and the seal resin. This provides the effect of improving an optical property.

In the first aspect, the multilayer film may be formed on one of both sides of the glass, and the seal resin may be formed between the other of both surfaces of the glass and the absorbing film. This provides the effect of improving an optical property when the seal resin is provided in two layers.

In the first aspect, the multilayer film may be formed on one of both sides of the glass, the absorbing film may be formed between the other of both surfaces of the glass and the seal resin, and the seal resin may be applied with a cavity. This provides the effect of improving the optical property of a CSP having a cavity.

In the first aspect, a difference between the refractive index of the absorbing film and the refractive index of the seal resin may not exceed 0.3. This provides the effect of reducing an optical loss.

In the first aspect, the glass may have higher hardness than the absorbing film, and the absorbing film may have higher hardness than the seal resin. This provides the effect of suppressing cracks and exfoliation of the glass.

In the first aspect, the absorbing film may have a side that is concave when viewed from a predetermined axis parallel to the substrate surface of the sensor substrate, and the seal resin may have a side that is convex when viewed from the predetermined axis. The provides the effect of suppressing the arrival of underfill at the glass.

In the first aspect, the multilayer film may cut off the infrared light components at a wavelength exceeding a cutoff wavelength that decreases as an incident angle of the incident light increases, and the absorption range may include the wavelength shift range of the cutoff wavelength. This provides the effect of sufficiently cutting off infrared light components.

In the first aspect, the absorption range may be a range of wavelengths with a transmittance not exceeding 3%, and a difference between the maximum wavelength and the minimum wavelength of the absorption range may be 50 to 200 nanometers. This provides the effect of reducing the thickness of the absorption film.

In the first aspect, the absorption range may be a range in a wave range of 650 to 900 nanometers. This provides the effect of absorbing infrared light components.

In the first aspect, the wavelength shift range may be a range from a wavelength shorter than the maximum wavelength by 100 nanometers to a predetermined wavelength. This provides the effect of improving an optical property.

In the first aspect, the multilayer film may further cut off ultraviolet light components. This provides the effect of improving the resistance of the CSP.

In the first aspect, the absorbing film may contain dyes of cyanin, phthalocyanine, or squarylium with a maximum value of absorptivity in a range of 700 to 800 nanometers. This provides the effect of absorption in the range of 700 to 800 nanometers.

A second aspect of the present technique is a semiconductor device including: an optical unit; a multilayer film that cuts off predetermined infrared light components of incident light from the optical unit; an absorbing film that absorbs components of a predetermined absorption range from transmitted light having passed through the multilayer film; and a sensor substrate that generates image data by photoelectrically converting light having passed through the absorbing film. This provides the effect of improving the optical property of the semiconductor device.

### BRIEF DESCRIPTION OF DRAWINGS

FIG. 1 is a cross-sectional view illustrating a configuration example of a semiconductor package according to a first embodiment of the present technique.

FIG. 2 is a cross-sectional view illustrating a configuration example of the semiconductor package according to a first comparative example.

FIG. 3 is an explanatory drawing of the function of an IR cutoff multilayer film according to the first embodiment of the present technique.

FIG. 4 is a cross-sectional view illustrating a configuration example of the semiconductor package according to the first embodiment and a second comparative example of the present technique.

FIG. 5 illustrates an example of an enlarged view of an end of the semiconductor package in the first embodiment and the first comparative example of the present technique.

FIG. 6 is a block diagram illustrating a configuration example of an imaging device in which the semiconductor package is mounted according to the first embodiment of the present technique.

FIG. 7 is a block diagram illustrating a configuration example of a solid-state image sensor according to the first embodiment of the present technique.

FIG. 8 is a graph indicating an example of a spectrum of transmitted light when incident light with an incident angle of 0° passes through the IR cutoff multilayer film according to the first embodiment of the present technique.

FIG. 9 is a graph indicating an example of a spectrum of transmitted light when incident light with an incident angle of 10° passes through the IR cutoff multilayer film according to the first embodiment of the present technique.

FIG. 10 is a graph indicating an example of a spectrum of transmitted light when incident light with an incident angle of 20° passes through the IR cutoff multilayer film according to the first embodiment of the present technique.

FIG. 11 is a graph indicating an example of a spectrum of transmitted light when incident light with an incident angle of 30° passes through the IR cutoff multilayer film according to the first embodiment of the present technique.

FIG. 12 is a graph indicating an example of a spectrum of transmitted light when incident light with an incident angle of 40° passes through the IR cutoff multilayer film according to the first embodiment of the present technique.

FIG. 13 is a graph indicating an example of a spectrum of transmitted light having passed through the IR cutoff multilayer film according to the first embodiment of the present technique.

FIG. 14 illustrates a configuration example of a CIS wafer according to the first embodiment of the present technique.

FIG. 15 illustrates a configuration example of a glass wafer according to the first embodiment of the present technique.

FIG. 16 illustrates a configuration example of a laminated wafer according to the first embodiment of the present technique.

FIG. 17 is a cross-sectional view illustrating a configuration example of a laminated wafer having a backside wire or the like according to the first embodiment of the present technique.

FIG. 18 is a cross-sectional view illustrating a configuration example of a laminated wafer in which the glass is reduced in thickness and the IR cutoff multilayer film is formed according to the first embodiment of the present technique.

FIG. 19 is a flowchart illustrating an example of a method for manufacturing the semiconductor package according to the first embodiment of the present technique.

FIG. 20 is a cross-sectional view illustrating a configuration example of a semiconductor package according to a second embodiment of the present technique.

FIG. 21 is a cross-sectional view illustrating a configuration example of a semiconductor package according to a third embodiment of the present technique.

FIG. 22 is a cross-sectional view illustrating a configuration example of a semiconductor package according to a fourth embodiment of the present technique.

FIG. 23 is a cross-sectional view illustrating a configuration example of a semiconductor package according to a fifth embodiment of the present technique.

FIG. 24 is a block diagram illustrating a schematic configuration example of a vehicle control system.

FIG. 25 is an explanatory diagram illustrating an example of installation positions of imaging units.

### DESCRIPTION OF EMBODIMENTS

Modes for carrying out the present technique (hereinafter also referred to as “embodiments”) will be described below. The description will be made in the following order.
1. First Embodiment (an example in which an IR cutoff absorbing film is disposed below an IR cutoff multilayer film)
2. Second Embodiment (an example in which an IR cutoff absorbing film is disposed below an IR cutoff multilayer film covering the top surface and sides of glass)
3. Third Embodiment (an example in which an IR cutoff absorbing film is disposed below an IR cutoff multilayer film on the underside of glass)
4. Fourth Embodiment (an example in which an IR cutoff absorbing film is disposed below an IR cutoff multilayer film and a seal resin is provided in two layers)
5. Fifth Embodiment (an example in which a cavity is formed and an IR cutoff absorbing film is disposed below an IR cutoff multilayer film)
6. Example of Application to Mobile Object

### 1. First Embodiment 2

### Configuration Example of Semiconductor Package

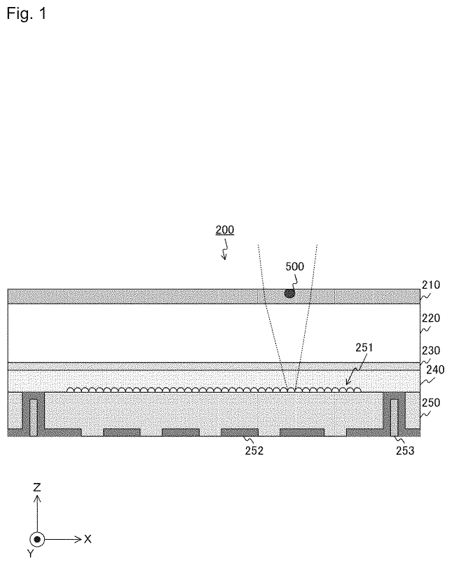

FIG. 1 is a cross-sectional view illustrating a configuration example of a semiconductor package 200 according to a first embodiment of the present technique. The semiconductor package 200 is a CSP that is a package of a solid-state image sensor and includes an IR cutoff multilayer film 210, a glass 220, an IR cutoff absorbing film 230, a seal resin 240, and a sensor substrate 250.

Hereinafter, an axis perpendicular to the substrate surface of the sensor substrate 250 will be referred to as “Z axis.” A predetermined axis perpendicular to “Z axis” will be referred to as “Y axis”, and an axis perpendicular to Z axis and Y axis will be referred to as “X axis.” FIG. 1 is a cross-sectional view of the semiconductor package 200 viewed in the Y-axis direction.

The sensor substrate 250 has the function of a solid-state image sensor that generates image data through photoelectric conversion. One of both surfaces of the sensor substrate 250 is an image surface on which a plurality of pixels 251 are arranged. The surface opposed to the image surface will be referred to as “back side,” and a direction from the back side to the image surface will be referred to as “upward” direction. On the back side of the sensor substrate 250, a backside wire 252 and a TSV 253 are formed.

The IR cutoff multilayer film 210 is formed on the top surface of the glass 220 (in other words, on the entry-side surface), and the IR cutoff absorbing film 230 is formed on the underside of the glass 220. The glass 220 has a thickness of, for example, 150 micrometers (μm) or less.

The IR cutoff multilayer film 210 is configured to cut off predetermined infrared light components of incident light and pass other components. The IR cutoff multilayer film 210 is configured with a laminated film that is a combination of a high-refractivity material, an intermediate-refractivity material, and a low-refractivity material. The IR cutoff multilayer film 210 is an example of a multilayer film described in the claims.

As a low-refractivity material constituting the IR cutoff multilayer film 210, for example, silicon dioxide, magnesium fluoride, calcium fluoride, or yttrium fluoride is used. The refractive indexes of silicon dioxide, magnesium fluoride, calcium fluoride, and yttrium fluoride are 1.46, 1.38, 1.43, and 1.52, respectively.

As an intermediate-refractivity material, for example, aluminum oxide, magnesium oxide, lanthanum fluoride, yttrium oxide, or cerium fluoride is used. The refractive indexes of aluminum oxide, magnesium oxide, lanthanum fluoride, yttrium oxide, and cerium fluoride are 1.60, 1.74, 1.59, 1.74, and 1.65, respectively.

As a high-refractivity material, for example, silicon nitride, silicon monoxide, titanium oxide, zirconium oxide, ceric oxide, zinc sulfide, tantalum oxide, hafnium oxide, tungsten oxide, niobium oxide, silicon, germanium, or zinc selenide is used. The refractive indexes of silicon nitride, silicon monoxide, titanium oxide, zirconium oxide, ceric oxide, zinc sulfide, tantalum oxide, hafnium oxide, tungsten oxide, niobium oxide, silicon, germanium, and zinc selenide are 2.00, 1.90, 2.40, 2.10, 2.35, 2.35, 2.20, 2.06, 2.14, 2.37, 3.40, 4.40, and 2.60, respectively.

The IR cutoff absorbing film 230 is configured to absorb components in a predetermined absorption range from light having passed through the IR cutoff multilayer film 210 and pass other components. The IR cutoff absorbing film 230 is formed by applying, by spin coating or the like, a solution containing dyes of cyanin, phthalocyanine, or squarylium with a maximum value of absorptivity in the range of 700 to 800 nanometers (nm). The IR cutoff multilayer film 210 considerably cuts off infrared light components, eliminating the need for using dyes that absorb components over a wide wave range when the IR cutoff absorbing film 230 is formed. Furthermore, components do not need to be absorbed over a wide wave range, so that the IR cutoff absorbing film 230 can have a small thickness of about 2 micrometers (μm). The IR cutoff absorbing film 230 is an example of an absorbing film described in the claims.

The seal resin 240 is applied between the IR cutoff absorbing film 230 and the image surface of the sensor substrate 250 without forming a cavity. Such a CSP structure is called a cavityless CSP structure. The cavityless CSP structure can reduce a thermal stress generated by a thermal process and suppress warpage of a wafer provided with the semiconductor package 200.

Moreover, the hardness of the glass 220 is higher than that of the IR cutoff absorbing film 230, and the hardness of the IR cutoff absorbing film 230 is higher than that of the seal resin 240. According to this relationship, the IR cutoff absorbing film 230 serves as a cushion when the semiconductor package is cut into pieces, thereby suppressing cracks and exfoliation of the glass 220.

In this case, it is assumed that a cavityless CSP with the IR cutoff multilayer film 210 formed on the underside of the glass 220 serves as a first comparative example.

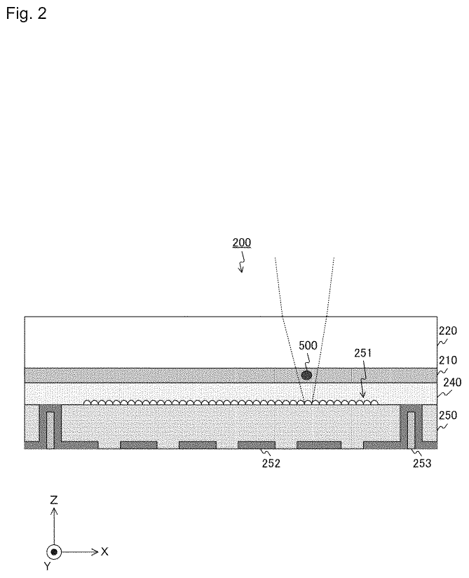

FIG. 2 is a cross-sectional view illustrating a configuration example of a semiconductor package according to the first comparative example. In the first comparative example, the IR cutoff absorbing film 230 is not formed and the seal resin 240 is applied between the underside of the IR cutoff multilayer film 210 on the underside of the glass 220 and the image surface. It is also assumed that dust 500 may be trapped in the film when the IR cutoff multilayer film 210 is formed. The dust 500 may cause a defect in image data and deteriorate the image quality.

Typically, in the Z-axis direction, the nearer the focal point of condensed light, the higher the luminous flux density, whereas the farther from the focal point, the lower the luminous flux density. Thus, by forming the IR cutoff multilayer film 210 on the top surface of the glass 220 as illustrated in FIG. 1, luminous fluxes blocked by the dust 500 can be reduced as compared with the first comparative example in which the IR cutoff multilayer film 210 is formed on the underside of the glass 220 as illustrated in FIG. 2. Consequently, the influence of image quality degradation caused by the dust 500 can be reduced, achieving a high-yield CSP with few defects.

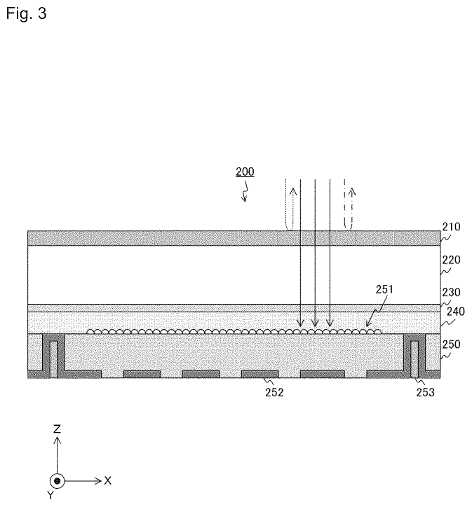

FIG. 3 is an explanatory drawing of the function of the IR cutoff multilayer film 210 according to the first embodiment of the present technique. A dotted line in FIG. 3 indicates ultraviolet light components, and solid lines in FIG. 3 indicate visible light components. A chain line indicates infrared light components.

As illustrated in FIG. 3, the IR cutoff multilayer film 210 can further cut off ultraviolet light components. The UV (Ultra Violet) cutoff function can improve the resistance of the CSP.

The IR cutoff multilayer film 210 can further have an AR (Anti Reflection) function. If the IR cutoff multilayer film 210 is formed on the underside of the glass 220 as in the first comparative example, an AR film needs to be formed on the top surface of the glass 220 in order to provide the AR function. The IR cutoff multilayer film 210 is configured with the AR function, thereby eliminating the need for separately forming the AR film and the IR cutoff multilayer film 210 on and under the glass 220. The films can be integrated into a single film.

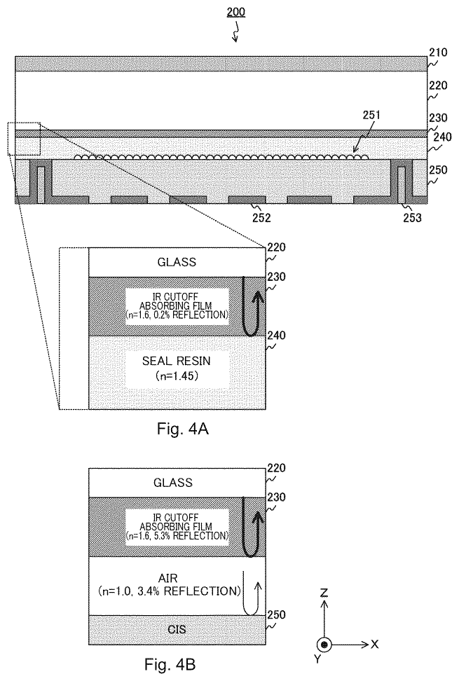

FIG. 4 is a cross-sectional view illustrating a configuration example of the semiconductor package according to the first embodiment and a second comparative example of the present technique. “a” in FIG. 4 is a cross-sectional view illustrating a configuration example of the semiconductor package 200 according to the first embodiment of the present technique. “b” in FIG. 4 is a cross-sectional view of the CSP of second comparative example. The second comparative example is a CSP including a cavity instead of the seal resin 240 between the IR cutoff absorbing film 230 and the image surface.

A difference between the refractive index of the IR cutoff absorbing film 230 and the refractive index of the seal resin 240 is preferably, for example, 0.3 or less. For example, the refractive index of the IR cutoff absorbing film 230 is 1.6, and the refractive index of the seal resin 240 is 1.45. In addition, the refractive index of air is typically about 1.0.

As illustrated in “a” of FIG. 4, by setting a difference between the refractive index of the IR cutoff absorbing film 230 and the refractive index of the seal resin 240 at 0.3 or less, the reflectivity of the interface can be brought to about 0.2 percent (%).

As illustrated in “b” of FIG. 4, in the second comparative example, the reflectivity of the interface between the IR cutoff absorbing film 230 and air is about 5.3 percent (%) and the reflectivity of the image surface is about 3.4 percent (%).

As illustrated in “a” and “b” of FIG. 4, the provision of the cavityless CSP structure reduces an optical loss more than in the second comparative example, achieving a CSP with high image quality.

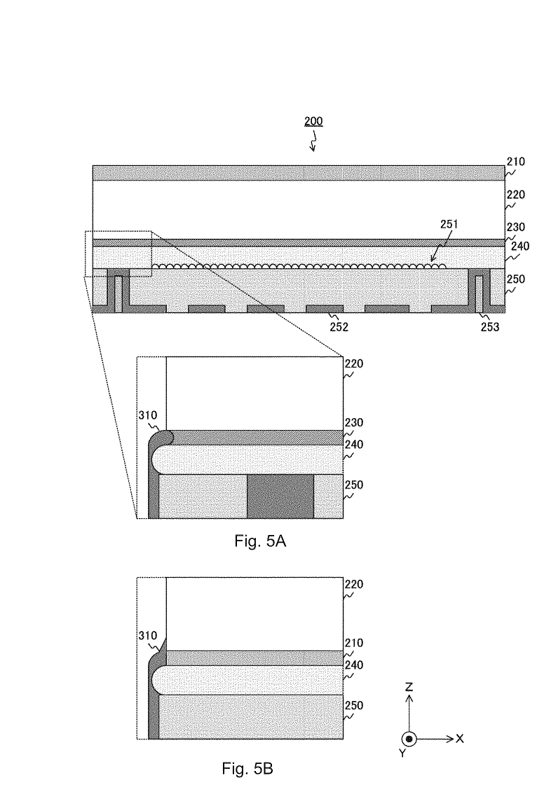

FIG. 5 illustrates an example of an enlarged view of an end of the semiconductor package in the first embodiment and the first comparative example of the present technique. “a” of FIG. 5 illustrates an example of an enlarged view of an end of the semiconductor package 200 in the first embodiment. “b” of FIG. 5 illustrates an example of an enlarged view of an end of the semiconductor package in the first comparative example.

As illustrated in “a” of FIG. 5, in the first embodiment, the side of the IR cutoff absorbing film 230 is concave when viewed from the Y axis parallel to the substrate surface of the sensor substrate 250. Furthermore, the side of the seal resin 240 is convex when viewed from the Y axis. At the time of sealing with an underfilling material 310, the underfilling material 310 climbs up on the side of the semiconductor package 200 but the climbing is suppressed by the convex portion of the seal resin 240. Moreover, the amount of climbing over the convex portion is absorbed by the concave portion of the IR cutoff absorbing film 230, thereby suppressing the arrival of the underfilling material 310 at the glass 220 provided on the IR cutoff absorbing film 230.

As illustrated in “b” of FIG. 5, in the first comparative example, the IR cutoff multilayer film 210 does not have a concave portion. In this case, the underfilling material 310 climbing over the convex portion of the seal resin 240 may reach the glass 220.

### Configuration Example of Imaging Device

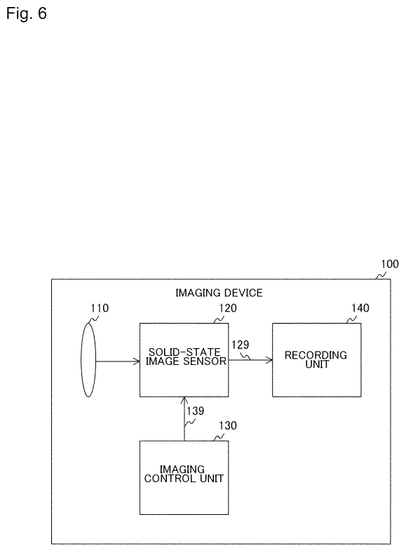

FIG. 6 is a block diagram illustrating a configuration example of an imaging device 100 in which the semiconductor package 200 is mounted according to the first embodiment of the present technique. The imaging device 100 of the first embodiment includes an optical unit 110, a solid-state image sensor 120, an imaging control unit 130, and a recording unit 140. It is assumed that a smartphone or an onboard camera with an imaging function serves as the imaging device 100. The imaging device 100 is an example of a semiconductor device described in the claims.

The optical unit 110 condenses light and guides the light to the solid-state image sensor 120. The solid-state image sensor 120 is configured to photoelectrically convert the incident light from the optical unit 110 and generate image data under the control of the imaging control unit 130. The solid-state image sensor 120 supplies the image data to the recording unit 140 via a signal line 129.

The imaging control unit 130 is configured to control the overall imaging device 100. The imaging control unit 130 supplies, for example, a vertical synchronizing signal indicating the timing of imaging, to the solid-state image sensor 120 via a signal line 139. The recording unit 140 is configured to record image data.

The semiconductor package 200 illustrated in FIG. 1 acts as the solid-state image sensor 120 in FIG. 6.

### Configuration Example of Solid-state Image Sensor

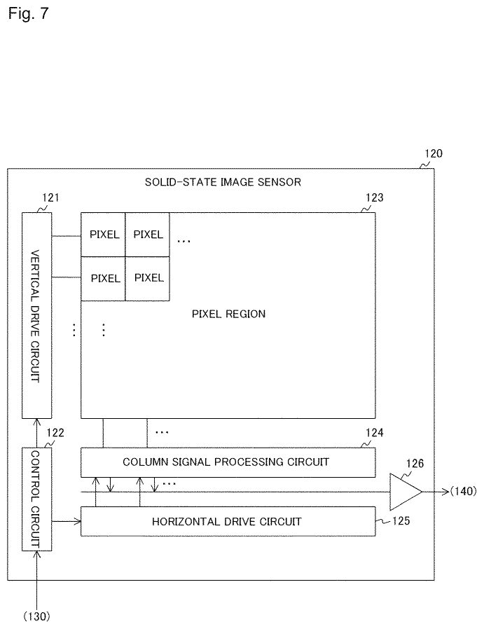

FIG. 7 is a block diagram illustrating a configuration example of the solid-state image sensor 120 according to the first embodiment of the present technique. The solid-state image sensor 120 of the first embodiment includes a vertical drive circuit 121, a control circuit 122, a pixel region 123, a column signal processing circuit 124, a horizontal drive circuit 125, and an output circuit 126. A plurality of pixels are arranged in a two-dimensional grid pattern in the pixel region 123.

The vertical drive circuit 121 includes, for example, a shift register and is configured to drive pixels for each row and output a pixel signal. The control circuit 122 controls the operation timing of the vertical drive circuit 121, the column signal processing circuit 124, and the horizontal drive circuit 125 in synchronization with a vertical synchronizing signal from the outside.

The column signal processing circuit 124 is configured to perform signal processing such as AD (Analog to Digital) conversion on pixel signals from each column of the pixel region 123. The column signal processing circuit 124 includes, for example, an ADC (Analog to Digital Converter) for each column and performs AD conversion according to a column ADC method or the like. Moreover, the column signal processing circuit 124 performs CDS (Correlated Double Sampling) processing for removing fixed pattern noise. The column signal processing circuit 124 supplies the processed image signal to the output circuit 126 under the control of the horizontal drive circuit 125.

The horizontal drive circuit 125 is configured to supply a horizontal scanning pulse signal to the column signal processing circuit 124 and sequentially output processed pixel signals under the control of the control circuit 122.

The output circuit 126 is configured to output image data, in which the pixel signals from the column signal processing circuit 124 are arranged, to the outside.

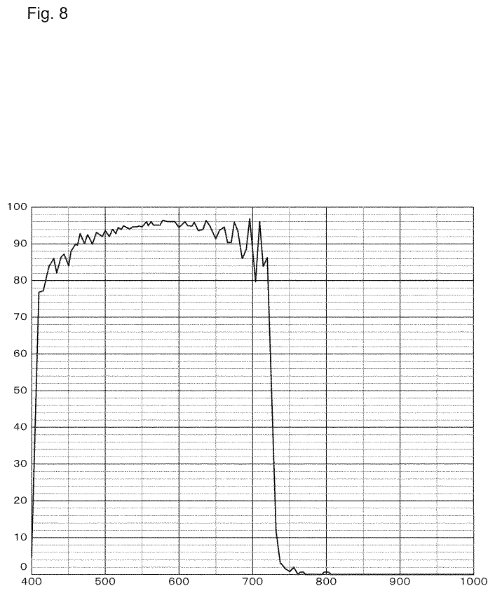

FIG. 8 is a graph indicating an example of a spectrum of transmitted light when incident light with an incident angle of 0° passes through the IR cutoff multilayer film 210 according to the first embodiment of the present technique. The vertical axis of FIG. 8 indicates the intensity of transmitted light as a percent with respect to incident light, and the horizontal axis indicates a wavelength.

Hereinafter, the minimum wavelength at which the transmittance of transmitted light is 3 percent (%) or less in a spectrum will be referred to as “cutoff wavelength.”

As shown in FIG. 8, at an incident angle of 0°, infrared light components at about 750 nanometers (nm) or more are cut from transmitted light. In other words, a cutoff wavelength λ_{CF}(0) is 750 nanometers (nm).

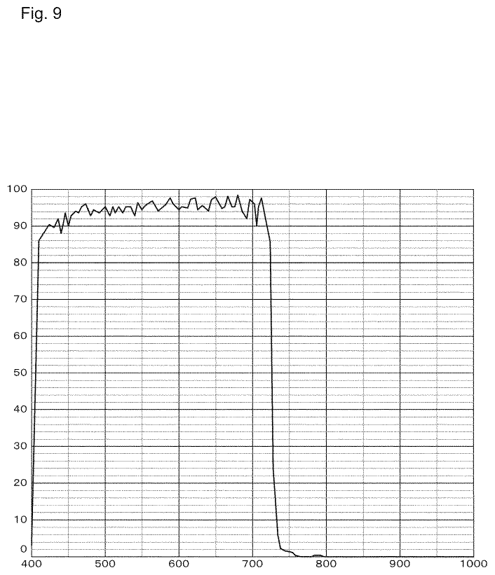

FIG. 9 is a graph indicating an example of a spectrum of transmitted light when incident light with an incident angle of 10° passes through the IR cutoff multilayer film 210. The vertical axis of FIG. 9 indicates the intensity of transmitted light as a percent with respect to incident light, and the horizontal axis indicates a wavelength.

As shown in FIG. 9, in the case of an incident angle of 10°, the cutoff wavelength λ_{CF}(10) is slightly shorter than λ_{CF}(0). Hereinafter, a cutoff wavelength for an incident angle θ larger than 0° is denoted as λ_{CF}(θ).

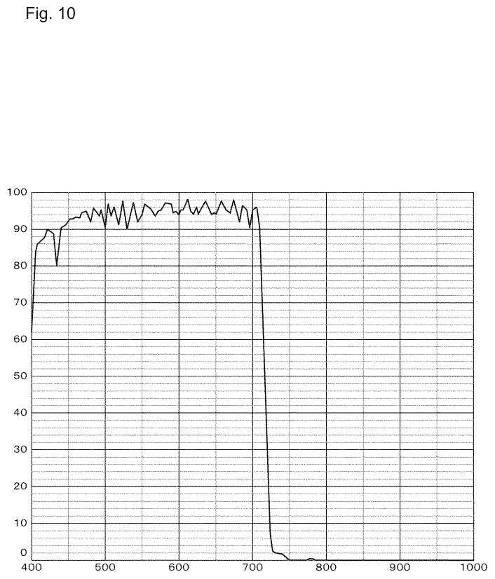

FIG. 10 is a graph indicating an example of a spectrum of transmitted light when incident light with an incident angle of 20° passes through the IR cutoff multilayer film 210 according to the first embodiment of the present technique. The vertical axis of FIG. 10 indicates the intensity of transmitted light as a percent with respect to incident light, and the horizontal axis indicates a wavelength.

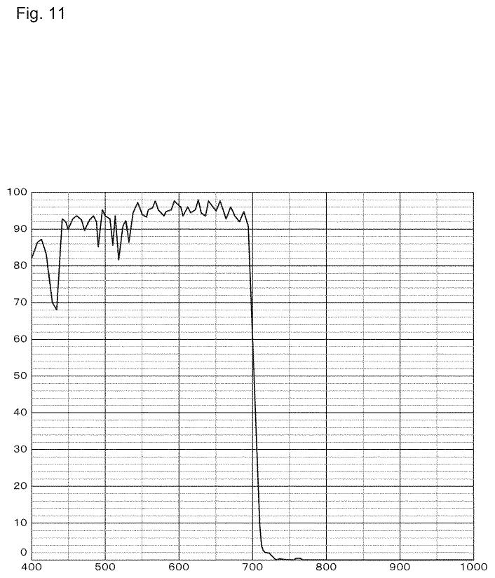

FIG. 11 is a graph indicating an example of a spectrum of transmitted light when incident light with an incident angle of 30° passes through the IR cutoff multilayer film 210 according to the first embodiment of the present technique. The vertical axis of FIG. 11 indicates the intensity of transmitted light as a percent with respect to incident light, and the horizontal axis indicates a wavelength.

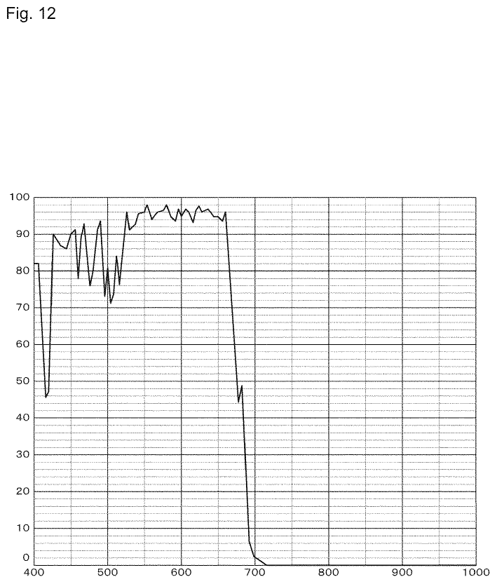

FIG. 12 is a graph indicating an example of a spectrum of transmitted light when incident light with an incident angle of 40° passes through the IR cutoff multilayer film 210 according to the first embodiment of the present technique. The vertical axis of FIG. 12 indicates the intensity of transmitted light as a percent with respect to incident light, and the horizontal axis indicates a wavelength.

As shown in FIGS. 8 to 12, the cutoff wavelength λ_{CF}(θ) decreases as the incident angle θ increases. The cutoff wavelength is typically expressed by the following formula:

$${λ}_{CF} ( θ ) = {λ}_{CF} ( 0 ) * cos ( θ ) \qquad Formula 1$$

In the formula represented above, “*” indicates multiplication and cos (indicates a cosine function.

Hereinafter, the range from the cutoff wavelength λ_{CF}(0) to the cutoff wavelength λ_{CF}(θ) at the maximum incident angle will be referred to as “wavelength shift range.” Moreover, a difference between the maximum wavelength and the minimum wavelength of the wavelength shift range will be referred to as “shift amount.” For example, if the maximum incident angle is set at 40° and the cutoff wavelength λ_{CF}(0) is set at 850 nanometers (nm), the cutoff wavelength λ_{CF}(40) is 651 nanometers (nm) and the shift amount is about 200 nanometers (nm).

However, by increasing the number of layers constituting the IR cutoff multilayer film 210, a design can be prepared such that the shift amount is smaller than a value (e.g., about 200 nanometers) obtained by Formula 1. In FIGS. 8 to 12, the shift amount is reduced to about 50 nanometers (nm) by increasing the number of constituent layers.

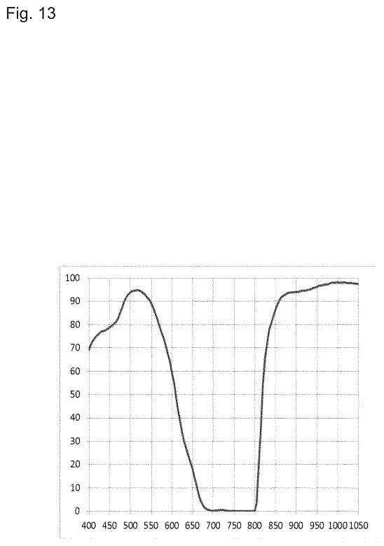

FIG. 13 is a graph indicating an example of a spectrum of transmitted light having passed through the IR cutoff multilayer film 230 according to the first embodiment of the present technique. The vertical axis of FIG. 13 indicates the intensity of transmitted light as a percent with respect to the intensity of incident light, and the horizontal axis indicates a wavelength.

Hereinafter, a wave range in which transmittance during passage through the IR cutoff absorbing film 230 does not exceed 3 percent (%) will be referred to as “absorption range.” A difference between the maximum wavelength and the minimum wavelength of the absorption range is preferably 50 to 200 nanometers (nm). Moreover, the absorption range is a range in the wave range of 650 to 900 nanometers (nm). In other words, the minimum wavelength of the absorption range is 650 nanometers (nm) or more, and the maximum wavelength of the absorption range is 900 nanometers (nm) or less. For example, in FIG. 13, the absorption range is 700 to 800 nanometers (nm).

It is assumed that the absorption range of the IR cutoff absorbing film 230 includes the wavelength shift range of the IR cutoff multilayer film 210.

For example, the wavelength shift range shown in FIGS. 8 to 12 is a range from a wavelength (about 700 nanometers), which is shorter than the maximum wavelength (about 800 nanometers) of the absorption range in FIG. 13 by 100 nanometers, to 750 nanometers. Thus, a cutoff wavelength (e.g., 700 nanometers) shifted with a large incident angle with respect to the IR cutoff multilayer film 210 falls within the absorption range, thereby obtaining an IRCF (IR Cut-off Filter) property with proper dependence on an incident angle. In other words, also in the case of a large incident angle, the IR cutoff multilayer film 210 and the IR cutoff absorbing film 230 can sufficiently cut off infrared light components, thereby improving an optical property for blocking infrared light components.

A method for manufacturing the semiconductor package 200 illustrated in FIG. 1 will be described below.

### Method for Manufacturing Semiconductor Package

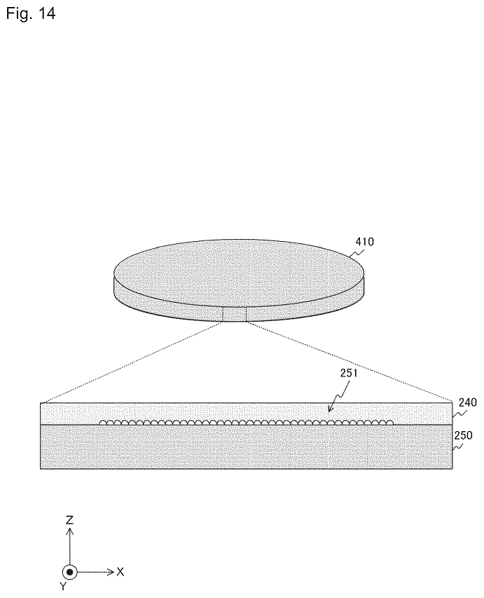

FIG. 14 illustrates a configuration example of a CIS wafer 410 according to the first embodiment of the present technique. On the CIS wafer 410, a glass wafer, which will be described later, is stacked and is subjected to dicing, so that a plurality of semiconductor packages 200 are manufactured.

As illustrated in FIG. 14, a manufacturing system for the semiconductor package 200 manufactures the CIS wafer 410. The CIS wafer 410 includes the sensor substrate 250. The plurality of pixels 251 are formed on the image surface of the sensor substrate 250, and the seal resin 240 is applied thereon. At this point, however, rewiring or a TSV is not formed on the backside of the CIS wafer 410.

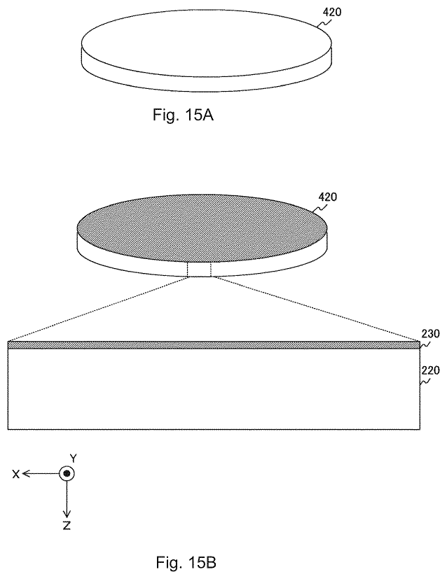

FIG. 15 illustrates a configuration example of a glass wafer 420 according to the first embodiment of the present technique. “a” in FIG. 15 illustrates an example of the glass wafer 420 before the IR cutoff absorbing film 230 is formed. “b” in FIG. 15 illustrates an example of the glass wafer 420 after the IR cutoff absorbing film 230 is formed.

The manufacturing system applies a solution containing dyes of cyanin or the like by spin coating to form the IR cutoff absorbing film 230 on one surface of the glass wafer 420.

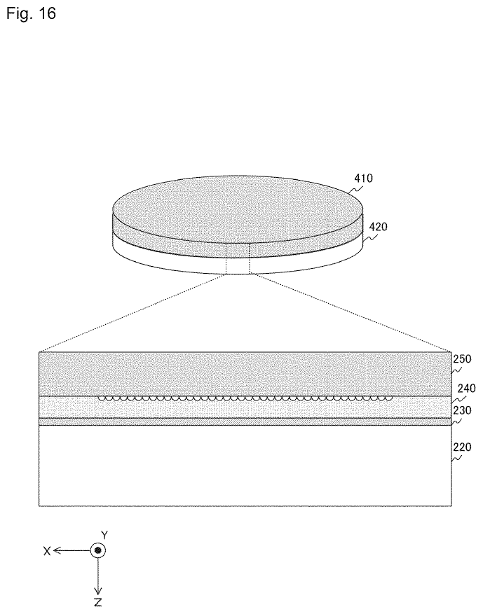

FIG. 16 illustrates a configuration example of a laminated wafer according to the first embodiment of the present technique. The manufacturing system manufactures the laminated wafer by bonding the image surface of the CIS wafer 410 illustrated in FIG. 14 and a surface of the IR cutoff absorbing film 230 of the glass wafer 420 illustrated in “b” of FIG. 15.

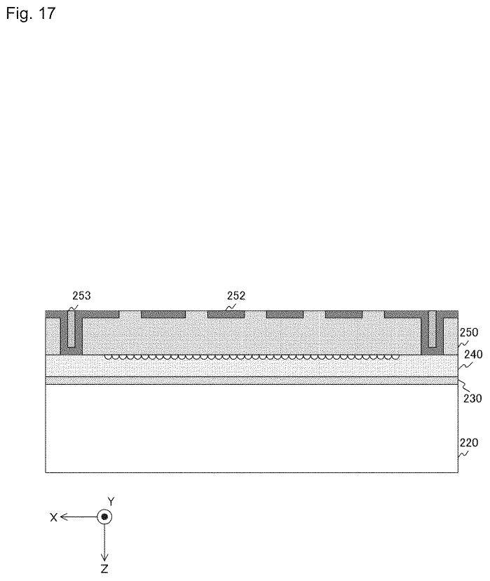

FIG. 17 is a cross-sectional view illustrating a configuration example of a laminated wafer having a backside wire or the like according to the first embodiment of the present technique. As illustrated in FIG. 17, the manufacturing system forms a backside wire 252 or a TSV 253 on the back side of the laminated wafer.

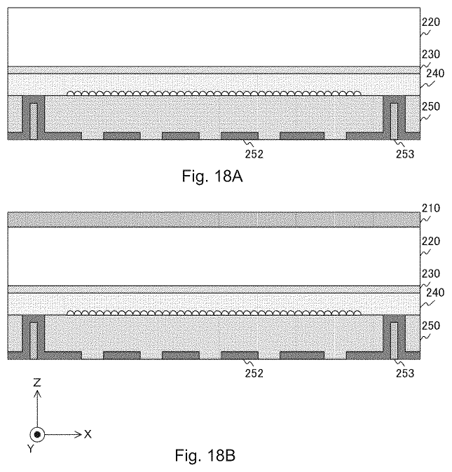

FIG. 18 is a cross-sectional view illustrating a configuration example of a laminated wafer in which the glass 220 is reduced in thickness and the IR cutoff multilayer film 210 is formed according to the first embodiment of the present technique. “a” in FIG. 18 is a cross-sectional view illustrating a configuration example of the laminated wafer in which the glass 220 is reduced in thickness. “b” in FIG. 18 is a cross-sectional view illustrating a configuration example of the laminated wafer in which the IR cutoff multilayer film 210 is formed after the glass 220 is reduced in thickness.

As illustrated in “a” of FIG. 18, the manufacturing system polishes the top surface of the glass 220 to a smaller thickness on the laminated wafer. As illustrated in “b” of FIG. 18, the manufacturing system forms the IR cutoff multilayer film 210 on the top surface of the glass 220. The manufacturing system then performs dicing on the laminated wafer. Thus, the plurality of semiconductor packages 200 are manufactured.

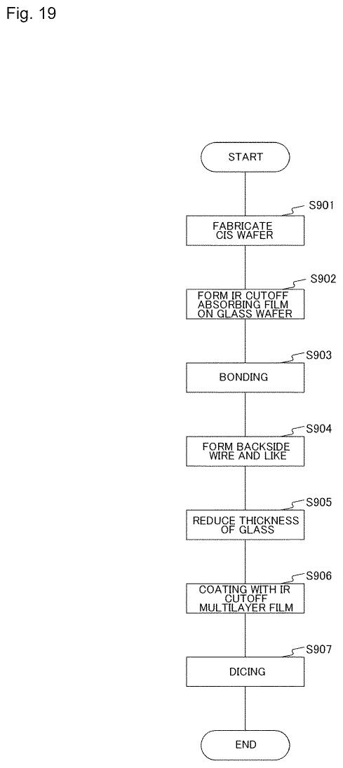

FIG. 19 is a flowchart showing an example of the method for manufacturing the semiconductor package 200 according to the first embodiment of the present technique. The manufacturing system fabricates the CIS wafer 410 (step S901). Furthermore, the manufacturing system forms the IR cutoff absorbing film 230 on one surface of the glass wafer 420 (step S902). In this case, step S901 and step S902 can be executed in parallel.

The manufacturing system fabricates the laminated wafer by bonding the image surface of the CIS wafer 410 and the surface of the IR cutoff absorbing film 230 of the glass wafer 420 (step S903). The manufacturing system then forms the backside wire 252 and the TSV 253 on the back side of the laminated wafer (step S904).

The manufacturing system polishes the top surface of the glass 220 on the laminated wafer to a smaller thickness (step S905) and forms the IR cutoff multilayer film 210 (step S906). Subsequently, the manufacturing system performs dicing on the laminated wafer (step S907) and terminates the manufacturing process of the semiconductor package 200.

FIG. 14 illustrates an example of the CIS wafer 410 fabricated in step S901. FIG. 15 illustrates an example of the glass wafer 420 manufactured in step S902. FIG. 16 illustrates an example of the laminated wafer manufactured in step S903. FIG. 17 illustrates an example of the laminated wafer at the time of step S904. FIG. 18 illustrates an example of the laminated wafer at the time of step S905 and step S906.

As described above, according to the first embodiment of the present technique, the IR cutoff absorbing film 230 is formed to absorb the components of the absorption range from transmitted light having passed through the IR cutoff multilayer film 210, thereby improving the optical property better than in the provision of the IR cutoff multilayer film 210 alone. Moreover, the design is prepared such that the absorption range includes the wavelength shift range, so that in the case of a large incident angle 6, infrared light components can be sufficiently cut off.

### 2. Second Embodiment

In the foregoing first embodiment, only the top surface of the glass 220 is covered with the IR cutoff multilayer film 210. In this configuration, the image quality of image data may be deteriorated by infrared light components from the sides. A semiconductor package 200 of a second embodiment is different from the first embodiment in that an IR cutoff multilayer film 210 covers the top surface and sides of a glass 220.

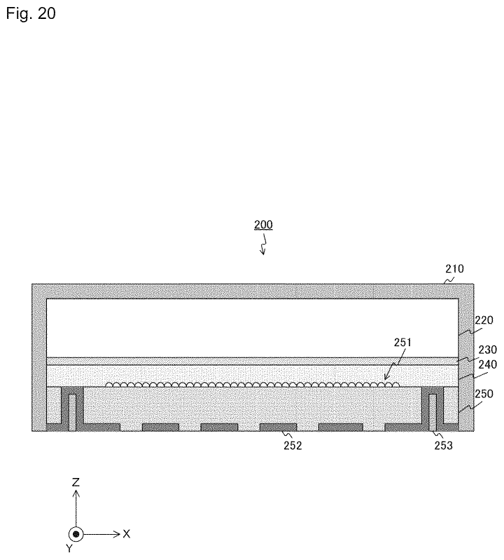

FIG. 20 is a cross-sectional view illustrating a configuration example of the semiconductor package 200 according to the second embodiment of the present technique. In the semiconductor package 200 of the second embodiment, the IR cutoff multilayer film 210 covers the sides of the glass 220 in addition to the top surface of the glass 220. Thus, infrared light components from the sides can be cut off, thereby improving the image quality of image data. Moreover, the resistance of the IR cutoff absorbing film 230 can be improved.

As described above, according to the second embodiment of the present technique, the IR cutoff multilayer film 210 covers the top surface and sides of the glass 220. This can further cut off infrared light components from the sides, thereby improving the image quality of image data.

### 3. Third Embodiment

In the foregoing first embodiment, the IR cutoff multilayer film 210 is formed on the top surface of the glass 220. The IR cutoff multilayer film 210 can be formed on the underside of the glass 220. A semiconductor package 200 of a third embodiment is different from the first embodiment in that an IR cutoff multilayer film 210 is formed on the underside of a glass 220.

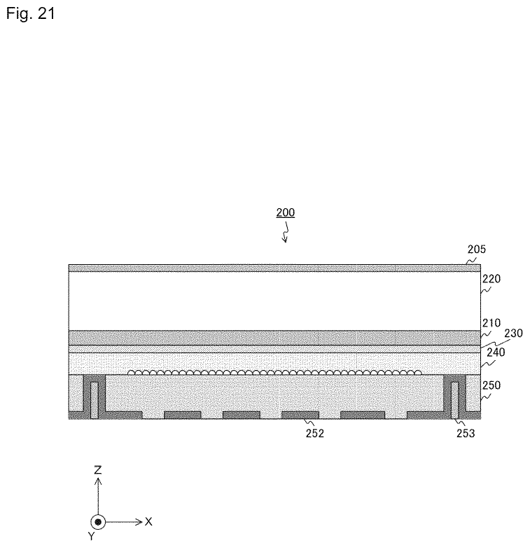

FIG. 21 is a cross-sectional view illustrating a configuration example of the semiconductor package 200 according to the third embodiment of the present technique. In the semiconductor package 200 of the third embodiment, an AR multilayer film 205 is formed on the top surface of the glass 220 and the IR cutoff multilayer film 210 is formed on the underside of the glass 220. Moreover, an IR cutoff absorbing film 230 is formed between the IR cutoff multilayer film 210 and a seal resin 240. The AR multilayer film 205 is an example of a first laminated film described in the claims, and the IR cutoff multilayer film 210 is an example of a second laminated film described in the claims.

As described above, according to the third embodiment of the present technique, the IR cutoff multilayer film 210 is formed on the underside of the glass 220, so that the optical property can be improved in the configuration where the IR cutoff multilayer film 210 is provided under the glass 220.

### 4. Fourth Embodiment

In the foregoing first embodiment, the seal resin 240 is applied between the IR cutoff absorbing film 230 and the sensor substrate 250. The IR cutoff absorbing film 230 can be formed near the sensor substrate 250. A semiconductor package 200 of a fourth embodiment is different from the first embodiment in that a seal resin 240 is disposed between a glass substrate 220 and an IR cutoff absorbing film 230.

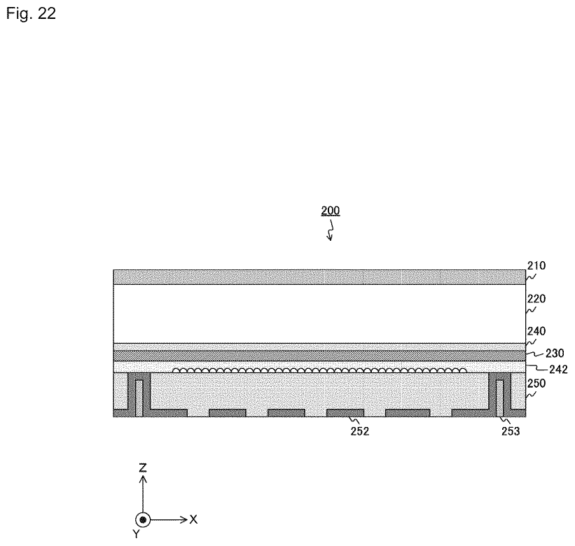

FIG. 22 is a cross-sectional view illustrating a configuration example of the semiconductor package 200 according to the fourth embodiment of the present technique. In the semiconductor package 200 of the fourth embodiment, the IR cutoff absorbing film 230 is disposed on a flattening layer 242 and the seal resin 240 is disposed between the glass substrate 220 and the IR cutoff absorbing film 230.

As described above, according to the fourth embodiment of the present technique, the seal resin 240 is disposed between the glass substrate 220 and the IR cutoff absorbing film 230, thereby improving the optical property.

### 5. Fifth Embodiment

In the foregoing first embodiment, the cavityless CSP structure is provided with the IR cutoff multilayer film 210 and the IR cutoff absorbing film 230. The IR cutoff multilayer film 210 and the IR cutoff absorbing film 230 may be provided for a CSP having a cavity. A semiconductor package 200 of a fifth embodiment is different from the first embodiment in that a cavity is formed.

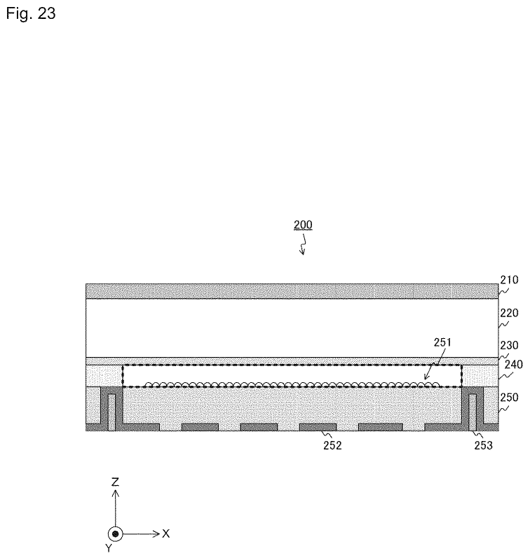

FIG. 23 is a cross-sectional view illustrating a configuration example of the semiconductor package 200 according to the fifth embodiment of the present technique. In the semiconductor package 200 of the fifth embodiment, a seal resin 240 is applied between the outer periphery of a pixel region on an image surface and an IR cutoff absorbing film 230. Thus, a cavity (a portion surrounded by a dotted line in FIG. 23) is formed above the image surface.

As described above, according to the fifth embodiment of the present technique, an IR cutoff multilayer film 210 and an IR cutoff absorbing film 230 are provided and the seal resin 240 is applied with a cavity, so that the optical property can be improved in a CSP having the cavity.

### 6. Example of Application to Mobile Object

The technique according to the present disclosure (the present technique) can be applied to various products. For example, the technique according to the present disclosure may be implemented as a device mounted in any type of mobile objects such as an automobile, an electric vehicle, a hybrid electric vehicle, a motorcycle, a bicycle, a personal mobility device, an airplane, a drone, a ship, and a robot.

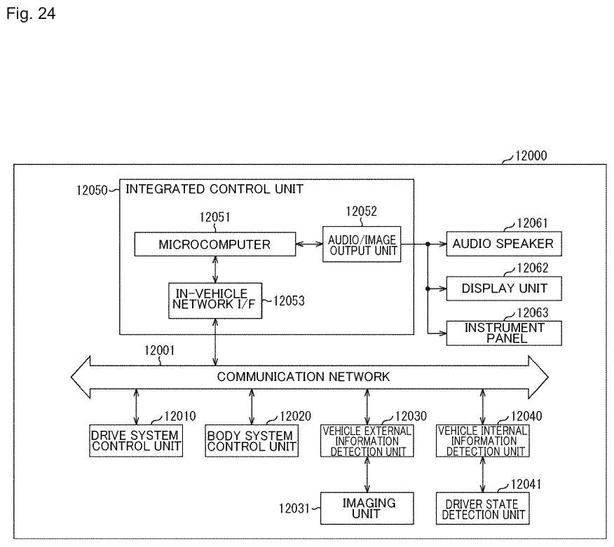

FIG. 24 is a block diagram showing a schematic configuration example of a vehicle control system that is an example of a mobile object control system to which the technique according to the present disclosure can be applied.

A vehicle control system 12000 includes a plurality of electronic control units connected via a communication network 12001. In the example illustrated in FIG. 24, the vehicle control system 12000 includes a drive system control unit 12010, a body system control unit 12020, a vehicle external information detection unit 12030, a vehicle internal information detection unit 12040, and an integrated control unit 12050. In addition, as a functional configuration of the integrated control unit 12050, a microcomputer 12051, an audio/image output unit 12052, and an in-vehicle network I/F (interface) 12053 are illustrated.

The drive system control unit 12010 controls an operation of an apparatus related to the drive system of a vehicle according to various programs. For example, the drive system control unit 12010 functions as a controller of a driving force generator for generating a driving force of a vehicle, for example, an internal combustion engine or a driving motor, a driving force transmission mechanism for transmitting a driving force to wheels, a steering mechanism for adjusting a turning angle of a vehicle, and a braking apparatus that generates a braking force of a vehicle.

The body system control unit 12020 controls operations of various devices mounted in the vehicle body, according to various programs. For example, the body system control unit 12020 functions as a controller of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be inputted to the body system control unit 12020. The body system control unit 12020 receives inputs of the radio waves or signals and controls a door lock device, a power window device, and a lamp of the vehicle.

The vehicle external information detection unit 12030 detects information on the outside of the vehicle having the vehicle control system 12000 mounted therein. For example, an imaging unit 12031 is connected to the vehicle external information detection unit 12030. The vehicle external information detection unit 12030 causes the imaging unit 12031 to capture an image of the outside of the vehicle and receives the captured image. The vehicle external information detection unit 12030 may perform object detection processing or distance detection processing for persons, automobiles, obstacles, signs, and letters on the road on the basis of the received image.

The imaging unit 12031 is an optical sensor that receives light and outputs an electrical signal according to the amount of the received light. The imaging unit 12031 can also output the electrical signal as an image or distance measurement information. In addition, the light received by the imaging unit 12031 may be visible light or invisible light such as infrared light.

The vehicle internal information detection unit 12040 detects information on the inside of the vehicle. For example, a driver state detection unit 12041 that detects a driver's state is connected to the vehicle internal information detection unit 12040. The driver state detection unit 12041 includes, for example, a camera that captures an image of a driver, and the vehicle internal information detection unit 12040 may calculate a degree of fatigue or concentration of the driver or may determine whether or not the driver is dozing on the basis of detection information inputted from the driver state detection unit 12041.

The microcomputer 12051 can calculate a control target value of the driving force generator, the steering mechanism, or the braking device on the basis of vehicle internal and external information acquired by the vehicle external information detection unit 12030 or the vehicle internal information detection unit 12040, and output a control command to the drive system control unit 12010. For example, the microcomputer 12051 can perform cooperative control for the purpose of implementing functions of an ADAS (Advanced Driver Assistance System), for example, collision avoidance or impact mitigation of a vehicle, following traveling based on an inter-vehicle distance, vehicle speed maintenance driving, vehicle collision warning, or vehicle lane deviation warning.

Furthermore, the microcomputer 12051 can perform cooperative control for the purpose of automated driving or the like in which autonomous traveling is performed without depending on operations of a driver, by controlling the driving force generator, the steering mechanism, or the braking device and the like on the basis of information about the surroundings of the vehicle, the information being acquired by the vehicle external information detection unit 12030 or the vehicle internal information detection unit 12040.

In addition, the microcomputer 12051 can output a control command to the body system control unit 12020 on the basis of the information acquired by the vehicle external information detection unit 12030 outside of the vehicle. For example, the microcomputer 12051 can perform cooperative control for the purpose of preventing glare, for example, switching from a high beam to a low beam by controlling the headlamp according to the position of a vehicle ahead or an oncoming vehicle detected by the vehicle external information detection unit 12030.

The audio/image output unit 12052 transmits an output signal of at least one of sound and an image to an output device capable of visually or audibly providing notification about information to a passenger or the outside of the vehicle. In the example of FIG. 24, as an output device, an audio speaker 12061, a display unit 12062 and an instrument panel 12063 are illustrated. The display unit 12062 may include, for example, at least one of an onboard display and a head-up display.

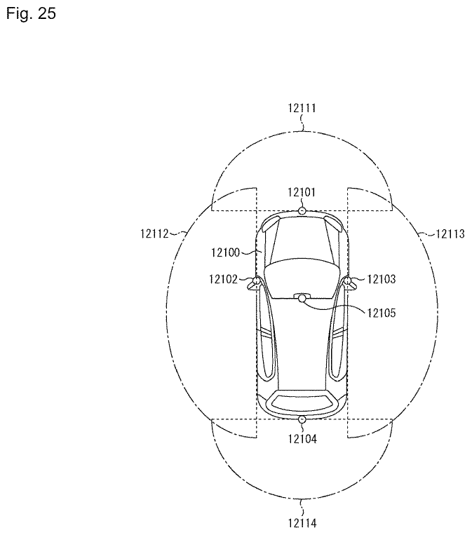

FIG. 25 illustrates an example of an installation position of the imaging unit 12031.

In FIG. 25, imaging units 12101, 12102, 12103, 12104, and 12105 are provided as the imaging unit 12031.

The imaging units 12101, 12102, 12103, 12104, and 12105 are provided at, for example, positions including a front nose, side-view mirrors, a rear bumper, a back door, and an upper portion of a windshield in a vehicle interior of the vehicle 12100. The imaging unit 12101 provided at the front nose and the imaging unit 12105 provided in the upper portion of the windshield in the vehicle interior mainly acquire images ahead of the vehicle 12100. The imaging units 12102 and 12103 provided at the side-view mirrors mainly acquire images on the sides of the vehicle 12100. The imaging unit 12104 provided at the rear bumper or the back door mainly acquires images behind the vehicle 12100. The imaging unit 12105 provided in the upper portion of the windshield in the vehicle interior is mainly used to detect a vehicle ahead, pedestrians, obstacles, traffic signals, traffic signs, lanes, and the like.

FIG. 25 illustrates an example of imaging ranges of the imaging units 12101 to 12104. An imaging range 12111 indicates the imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, by superimposing image data captured by the imaging units 12101 to 12104, a bird's-eye view image viewed from above the vehicle 12100 can be obtained.

At least one of the imaging units 12101 to 12104 may have a function for obtaining distance information. For example, at least one of the imaging units 12101 to 12104 may be a stereo camera including a plurality of imaging elements or may be an imaging element having pixels for phase difference detection.

For example, the microcomputer 12051 acquires a distance to each of three-dimensional objects in the imaging ranges 12111 to 12114 and temporal change in the distance (a relative speed with respect to the vehicle 12100) on the basis of the distance information obtained from the imaging units 12101 to 12104, thereby extracting, as a vehicle ahead, a closest three-dimensional object particularly on a path along which the vehicle 12100 is traveling, that is, a three-dimensional object traveling at a predetermined speed (for example, 0 km/h or higher) in the substantially same direction as the vehicle 12100. Furthermore, the microcomputer 12051 can set an inter-vehicle distance to be secured in front of the vehicle in advance with respect to the vehicle ahead and can perform automated brake control (also including following stop control) or automated acceleration control (also including following start control). In this way, cooperative control can be performed for the purpose of automated driving or the like in which a vehicle autonomously travels without depending on an operation of the driver.

For example, the microcomputer 12051 can classify and extract three-dimensional data regarding three-dimensional objects into two-wheeled vehicles, ordinary vehicles, large-sized vehicles, pedestrians, and other three-dimensional objects such as electric poles on the basis of distance information obtained from the imaging units 12101 to 12104, and can use the three-dimensional data to perform automated avoidance of obstacles. For example, the microcomputer 12051 differentiates obstacles around the vehicle 12100 into obstacles viewable by the driver of the vehicle 12100 and obstacles that are difficult to view. The microcomputer 12051 then determines a collision risk indicating the degree of risk of collision with each obstacle, and when the collision risk is equal to or higher than a set value and there is a possibility of collision, an alarm is outputted to the driver through the audio speaker 12061 or the display unit 12062 or forced deceleration or avoidance steering is performed through the drive system control unit 12010, thereby providing driving assistance for collision avoidance.

At least one of the imaging units 12101 to 12104 may be an infrared camera that detects infrared rays. For example, the microcomputer 12051 can recognize a pedestrian by determining the presence or absence of a pedestrian in the captured images of the imaging units 12101 to 12104. Such pedestrian recognition is performed by, for example, the step of extracting feature points in the captured images of the imaging units 12101 to 12104 serving as infrared cameras and the step of performing pattern matching on a series of feature points indicating an outline of an object to determine whether the object is a pedestrian. When the microcomputer 12051 determines that a pedestrian is present in the captured images of the imaging units 12101 to 12104 and the pedestrian is recognized, the audio/image output unit 12052 controls the display unit 12062 such that a square contour line for emphasis is displayed while being superimposed on the recognized pedestrian. In addition, the audio/image output unit 12052 may control the display unit 12062 such that an icon or the like indicating a pedestrian is displayed at a desired position.

An example of the vehicle control system to which the technique according to the present disclosure is applicable was described above. The technique according to the present disclosure can be applied to the imaging unit 12031 among the configurations described above. Specifically, the imaging device 100 of FIG. 6 can be applied to, for example, the imaging unit 12031. By applying the technique according to the present disclosure to the imaging unit 12031, the optical property can be improved to capture a clearer image, thereby reducing driver fatigue.

It should be noted that the above-described embodiments show examples for embodying the present technique, and matters in the embodiments and matters specifying the invention in the claims are correlated with each other. Similarly, the matters specifying the invention in the claims and the matters having the same name in the embodiments of the present technique are correlated with each other. However, the present technique is not limited to the embodiments and can be embodied by applying various modifications to the embodiments without departing from the gist thereof.

The effects described in the present specification are merely examples and are not intended as limiting, and other effects may be obtained.

The present technique can also be configured as follows:
(1) A semiconductor package including: a multilayer film that cuts off predetermined infrared light components of incident light;
an absorbing film that absorbs components of a predetermined absorption range from transmitted light having passed through the multilayer film; and
a sensor substrate that generates image data by photoelectrically converting light having passed through the absorbing film.
(2) The semiconductor package according to (1), further including: a glass; and a seal resin applied between the glass and the sensor substrate.
(3) The semiconductor package according to (2), wherein the multilayer film is formed on one of both surfaces of the glass,
the absorbing film is formed between the other of both surfaces of the glass and the seal resin, and
the seal resin is applied without forming a cavity.
(4) The semiconductor package according to (2), wherein the multilayer film covers one of both surfaces of the glass and sides of the glass, and
the absorbing film is formed between the other of both surfaces of the glass and the seal resin.

(5) The semiconductor package according to (2), wherein the multilayer film includes a first multilayer film and a second multilayer film,
the first multilayer film is formed on one of both surfaces of the glass, and
the second multilayer film is formed between the other of both surfaces of the glass and the seal resin.
(6) The semiconductor package according to (2), wherein the multilayer film is formed on one of both surfaces of the glass,
the seal resin is formed between the other of both surfaces of the glass and the absorbing film.
(7) The semiconductor package according to (2), wherein the multilayer film is formed on one of both surfaces of the glass,
the absorbing film is formed between the other of both surfaces of the glass and the seal resin, and
the seal resin is applied with a cavity.
(8) The semiconductor package according to (2), wherein a difference between a refractive index of the absorbing film and a refractive index of the seal resin does not exceed 0.3.
(9) The semiconductor package according to (2), wherein the glass has higher hardness than the absorbing film, and
the absorbing film has higher hardness than the seal resin.
(10) The semiconductor package according to any one of (2) to (9), wherein the absorbing film has a side that is concave when viewed from a predetermined axis parallel to a substrate surface of the sensor substrate, and
the seal resin has a side that is convex when viewed from the predetermined axis.
(11) The semiconductor package according to any one of (1) to (10), wherein the multilayer film cuts off the infrared light components at a wavelength exceeding a cutoff wavelength that decreases as an incident angle of the incident light increases, and
the absorption range includes a wavelength shift range of the cutoff wavelength.
(12) The semiconductor package according to (11), wherein the absorption range is a range of wavelengths with a transmittance not exceeding 3%, and
a difference between a maximum wavelength and a minimum wavelength of the absorption range is 50 to 200 nanometers.
(13) The semiconductor package according to (11) or (12), wherein the absorption range is a range in a wave range of 650 to 900 nanometers.
(14) The semiconductor package according to (11) or (13), wherein the wavelength shift range is a range from a wavelength shorter than the maximum wavelength by 100 nanometers to a predetermined wavelength.
(15) The semiconductor package according to any one of (1) to (14), wherein the multilayer film further cuts off ultraviolet light components.
(16) The semiconductor package according to any one of (1) to (15), wherein the absorbing film contains dyes of cyanin, phthalocyanine, or squarylium with a maximum value of absorptivity in a range of 700 to 800 nanometers.
(17) A semiconductor device including: an optical unit;
a multilayer film that cuts off predetermined infrared light components of incident light from the optical unit;
an absorbing film that absorbs components of a predetermined absorption range from transmitted light having passed through the multilayer film; and
a sensor substrate that generates image data by photoelectrically converting light having passed through the absorbing film.
(18) A method for manufacturing a semiconductor package, the method including:
fabricating a CIS (CMOS Image Sensor) wafer including a sensor substrate that generates image data by photoelectrically converting light having passed through an absorbing film;
forming the absorbing film on one surface of a glass wafer, the absorbing film absorbing components of a predetermined absorption range from transmitted light having passed through a multilayer film that cuts off predetermined infrared light components of incident light;
fabricating a laminated wafer by bonding the CIS wafer and the glass wafer; and forming the multilayer film on the laminated wafer.

### REFERENCE SIGNS LIST

100 Imaging device
110 Optical unit
120 Solid-state image sensor
121 Vertical drive circuit
122 Control circuit
123 Pixel region
124 Column signal processing circuit
125 Horizontal drive circuit
126 Output circuit
130 Imaging control unit
140 Recording unit
200 Semiconductor package
205 AR multilayer film
210 IR cutoff multilayer film
220 Glass
230 IR cutoff absorbing film
240 Seal resin
242 Flattening layer
250 Sensor substrate
251 Pixel
252 Backside wire
253 TSV
310 Underfilling material
410 CIS wafer
420 Glass wafer
12031 Imaging unit

1. A semiconductor package comprising: a multilayer film that cuts off predetermined infrared light components of incident light;
an absorbing film that absorbs components of a predetermined absorption range from transmitted light having passed through the multilayer film; and
a sensor substrate that generates image data by photoelectrically converting light having passed through the absorbing film.

2. The semiconductor package according to claim 1, further comprising: a glass; and
a seal resin applied between the glass and the sensor substrate.

3. The semiconductor package according to claim 2, wherein the multilayer film is formed on one of both surfaces of the glass,
the absorbing film is formed between the other of both surfaces of the glass and the seal resin, and
the seal resin is applied without forming a cavity.

4. The semiconductor package according to claim 2, wherein the multilayer film covers one of both surfaces of the glass and sides of the glass, and
the absorbing film is formed between the other of both surfaces of the glass and the seal resin.

5. The semiconductor package according to claim 2, wherein the multilayer film includes a first multilayer film and a second multilayer film,
the first multilayer film is formed on one of both surfaces of the glass, and the second multilayer film is formed between the other of both surfaces of the glass and the seal resin.

6. The semiconductor package according to claim 2, wherein the multilayer film is formed on one of both surfaces of the glass,
the seal resin is formed between the other of both surfaces of the glass and the absorbing film.

7. The semiconductor package according to claim 2, wherein the multilayer film is formed on one of both surfaces of the glass,
the absorbing film is formed between the other of both surfaces of the glass and the seal resin, and
the seal resin is applied with a cavity.

8. The semiconductor package according to claim 2, wherein a difference between a refractive index of the absorbing film and a refractive index of the seal resin does not exceed 0.3.

9. The semiconductor package according to claim 2, wherein the glass has higher hardness than the absorbing film, and
the absorbing film has higher hardness than the seal resin.

10. The semiconductor package according to claim 2, wherein the absorbing film has a side that is concave when viewed from a predetermined axis parallel to a substrate surface of the sensor substrate, and
the seal resin has a side that is convex when viewed from the predetermined axis.

11. The semiconductor package according to claim 1, wherein the multilayer film cuts off the infrared light components at a wavelength exceeding a cutoff wavelength that decreases as an incident angle of the incident light increases, and
the absorption range includes a wavelength shift range of the cutoff wavelength.

12. The semiconductor package according to claim 11, wherein the absorption range is a range of wavelengths with a transmittance not exceeding 3%, and
a difference between a maximum wavelength and a minimum wavelength of the absorption range is 50 to 200 nanometers.

13. The semiconductor package according to claim 11, wherein the absorption range is a range in a wave range of 650 to 900 nanometers.

14. The semiconductor package according to claim 11, wherein the wavelength shift range is a range from a wavelength shorter than the maximum wavelength by 100 nanometers to a predetermined wavelength.

15. The semiconductor package according to claim 1, wherein the multilayer film further cuts off ultraviolet light components.

16. The semiconductor package according to claim 1, wherein the absorbing film contains dyes of cyanin, phthalocyanine, or squarylium with a maximum value of absorptivity in a range of 700 to 800 nanometers.

17. A semiconductor device comprising: an optical unit;
a multilayer film that cuts off predetermined infrared light components of incident light from the optical unit;
an absorbing film that absorbs components of a predetermined absorption range from transmitted light having passed through the multilayer film; and
a sensor substrate that generates image data by photoelectrically converting light having passed through the absorbing film.

18. A method for manufacturing a semiconductor package, the method comprising:
fabricating a CIS (CMOS Image Sensor) wafer including a sensor substrate that generates image data by photoelectrically converting light having passed through an absorbing film;
forming the absorbing film on one surface of a glass wafer, the absorbing film absorbing components of a predetermined absorption range from transmitted light having passed through a multilayer film that cuts off predetermined infrared light components of incident light;
fabricating a laminated wafer by bonding the CIS wafer and the glass wafer; and
forming the multilayer film on the laminated wafer.
